(19) United States
(12) Patent Application Publication
(10) Pub. No.: US 2010/0050929 A1
(43) Pub. Date: Mar. 4, 2010

(54) Coil Arrangement for Crystal Pulling and Method of Forming a Crystal

(75) Inventors: Achim Hobl, Roesrath (DE); Bernhard Fischer, Wuppertal (DE)

Correspondence Address: KOHLER SCHMID MOEBUS, RUPPMANNSTRASSE 27, D-70565 STUTTGART, DE

(73) Assignee: ACCEL INSTRUMENTS GMBH, Bergisch-Gladbach (DE)

(21) Appl. No.: 12/199,085

(22) Filed: Aug. 27, 2008

(51) Int. Cl. C30B 19/00

(52) U.S. Cl. 117/13; 117/208

(57) ABSTRACT

Coil arrangement for crystal pulling comprising two coils, wherein at least one of said two coils is arranged in a way to substantially surround the crystal and/or the fluid the crystal is pulled from. Method of forming a crystal comprising the steps of providing a fluid the crystal is pulled from, and providing two coils, wherein at least one of said two coils is arranged in a way to substantially surround the crystal and/or the fluid, and pulling the crystal from the fluid.

### TECHNICAL FIELD

The present invention relates to a coil arrangement for crystal pulling. Such coil arrangements are used to generate magnetic fields for manipulating the process of crystal pulling, when the crystal is pulled from a fluid, in particular from a melt. The magnetic fields used are usually parallel or perpendicular to the pulling axis, for example horizontal or vertical fields when the pulling axis is vertical. When the crystal is pulled from a melt, the predominant effect of the magnetic fields is to reduce the convective flow of the melt. The invention further relates to a method of forming a crystal providing coils to generate magnetic fields.

### BACKGROUND

A coil arrangement for crystal pulling is known from US patent application US2004/0107894 A1. According to this arrangement, a plurality of pairs of coils is arranged around a cylindrical pulling furnace in which the crystal is pulled. This arrangement has the disadvantage that it requires a large number of coils in order to provide a magnetic field of desired homogeneity. Other known coil arrangements use saddle-type coils which are complicated, risky and expensive to produce.

### SUMMARY

It is an object of the present invention to provide coil arrangements which avoid the disadvantages of the arrangements known from the prior art. It is another object of the present invention to provide coil arrangements which require only a low number of coils, preferably only two coils. Another object of the present invention is to provide coil arrangements which allow generation of a highly uniform magnetic field while at the same time keeping the arrangement and the shape of the coils simple.

Embodiments of the invention may achieve one or more of the above stated objects. The present invention provides, in one aspect, a coil arrangement for crystal pulling comprising two coils, whereby at least one of said two coils is arranged in a way to substantially surround the crystal and/or the fluid the crystal is pulled from. The fluid from which the crystal is pulled can be, for example, a melt. Substantially surrounding the crystal and/or the fluid means in the present disclosure that the coil extends over all or most of the way around the diameter of the growing crystal and/or the fluid. The coil need not entirely encircle the crystal and/or the fluid, and may instead nearly encircle the crystal and/or the fluid so long as it provides a sufficiently uniform magnetic field. With such coil arrangement, a partial magnetic field of good homogeneity may be provided by the coil substantially surrounding the crystal and/or the fluid. In a preferred embodiment, both of said two coils are arranged in a way to substantially surround the crystal and/or the fluid. Such arrangement allows that both coils provide uniform partial magnetic fields at the location of the crystal and/or in the fluid which superimpose and generate a resulting magnetic field. In another preferred embodiment, the two coils are canted with respect to each other. This arrangement allows the generation of superimposed resulting magnetic fields with preferred properties. In a further preferred embodiment, the two canted coils are arranged at symmetrical angles with respect to a horizontal plane. This allows easy generation of magnetic fields parallel to the horizontal plane as for example, as used when the pulling axis is vertical. In another preferred embodiment, the coils are arranged so as to provide a superimposed resulting dipole magnetic field. This dipole magnetic field can be, for example, parallel to a horizontal plane by arranging two coils at a symmetrical angle with respect to the horizontal plane.

In another preferred embodiment, the two coils are nested. In a further preferred embodiment, the coils are nested in such way that one coil is inside the other coil. Such arrangement can, for example, be produced by two coils with one coil having an outer diameter smaller than the inner diameter of the other coil. In another further preferred embodiment, the two coils are nested like two connected rings. Such arrangement can be produced, for example, by two flat, ring-like coils where one ring-like coil goes through the other and vice versa.

In another preferred embodiment, the cross-section of the coils, i.e., the form of the coil windings, is of round and/or elliptical and/or quadratic and/or rectangular shape. In an alternate embodiment, the cross-section of each coil is designed individually to optimize symmetry and homogeneity of the partial and/or resulting magnetic field profiles.

In another preferred embodiment, the longitudinal section of the coils, i.e., the section along the axes of the coils, have the shape of a rectangle and/or a parallelogram and/or curved shape.

In another preferred embodiment, the angle between the coils or, more particularly, the angle between cross-sectional planes through the coils can be varied, preferably between 0° and 180°. Such variation allows modification of the superimposed resulting magnetic field.

In other preferred embodiments, the coils are either powered individually or connected in series to be operated from one current source.

In other preferred embodiments, the coils can be superconducting or normal conducting. In case of superconducting coils, the coils might be operated as conduction-cooled without liquids, conduction-cooled with linked cooling channels or pipes or in a liquid helium bath. In other preferred embodiments, the coils can be powered with DC or AC currents or a combination of both.

In another preferred embodiment, the coil arrangement comprises additional coils also substantially surrounding the crystal and/or the fluid and preferably nested with the other coils.

In a further aspect, the invention provides a method of forming a crystal comprising a step of providing a fluid from which the crystal is pulled from, a the step of providing two coils, wherein at least one of said two coils is arranged in a way to substantially surround the crystal and/or the fluid the crystal is pulled from, and the step of pulling the crystal from the fluid.

According to such method, a crystal may be formed by pulling the crystal from a fluid, in particular from a melt, while coils may be arranged in a very simple, and, at the same time, very effective way for manipulating the process of crystal pulling, for example effectively reducing the convective flow in a melt from which the crystal is pulled.

An example embodiment of the present invention will be described herein with reference to the attached figures.

### BRIEF DESCRIPTION OF THE DRAWINGS

FIG. 1 shows a perspective view of a coil arrangement according to an embodiment of the present invention,

FIG. 2 shows a schematic side view of the coil arrangement shown in FIG. 1,

FIG. 3 shows a schematic side view of the coil arrangement shown in FIG. 1 with arrows showing the direction of partial and resulting magnetic fields,

FIG. 4 shows the magnetic field vectors of the partial and resulting magnetic fields generated by the coil arrangement shown in FIG. 1, and

FIG. 5 shows a top view of the coil arrangement shown in FIG. 1.

### DETAILED DESCRIPTION

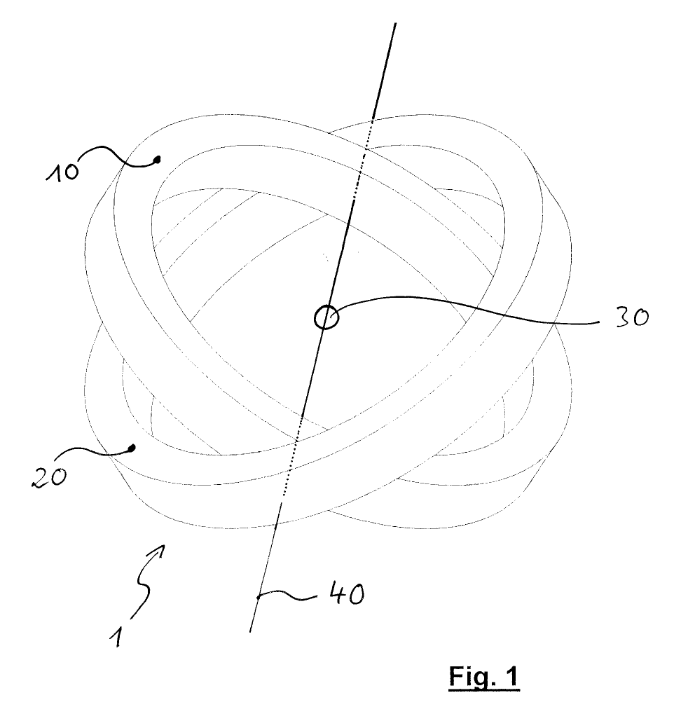

FIG. 1 shows a coil arrangement 1 according to an embodiment of the present invention. The arrangement consists of two coils, an inner coil 10 and an outer coil 20. Both coils are flat and have elliptical form. The smallest outer diameter of the inner coil 10 is smaller than the smallest inner diameter of the outer coil 20. This allows the coils to nest as shown in FIG. 1 where the inner coil is within the outer coil. In a similar way circular coils or coils of other shapes may be nested, provided that the outer diameter of the inner coil is smaller than the inner diameter of the outer coil. Both coils shown in FIG. 1 embrace and surround the location 30 of the crystal or crystal seed to be pulled. The location 30 of the crystal or crystal seed to be pulled is within the interior volume of both coils 10 and 20.

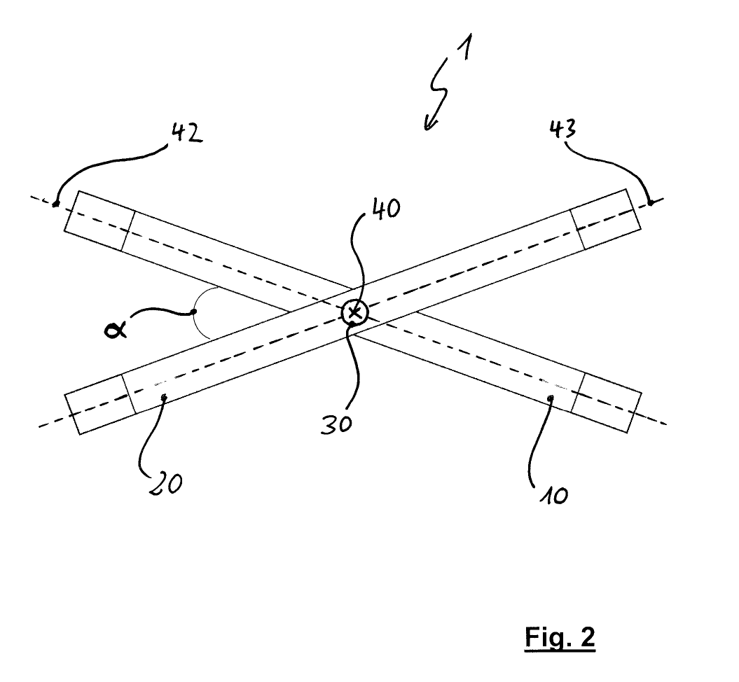

FIG. 2 shows a schematic side view of the coil arrangement shown in FIG. 1. As shown in FIGS. 1 and 2, inner and outer coil 10 and 20 are canted at an angle a. Cross-section planes 42 and 43 through the middle of coils 10 and 20 intersect, forming the axis 40. The location 30 of the crystal is located along the intersection axis 40. The angle a between inner and outer coil 10 and 20 may be varied over a broad range between 0° and 180°, preferably between 20° and 160°, and more preferably between 30° and 120°. While turning the coils, the location 30 of the crystal remains within the interior volume of both coils, such that it remains embraced and surrounded by both the inner and outer coils 10 and 20.

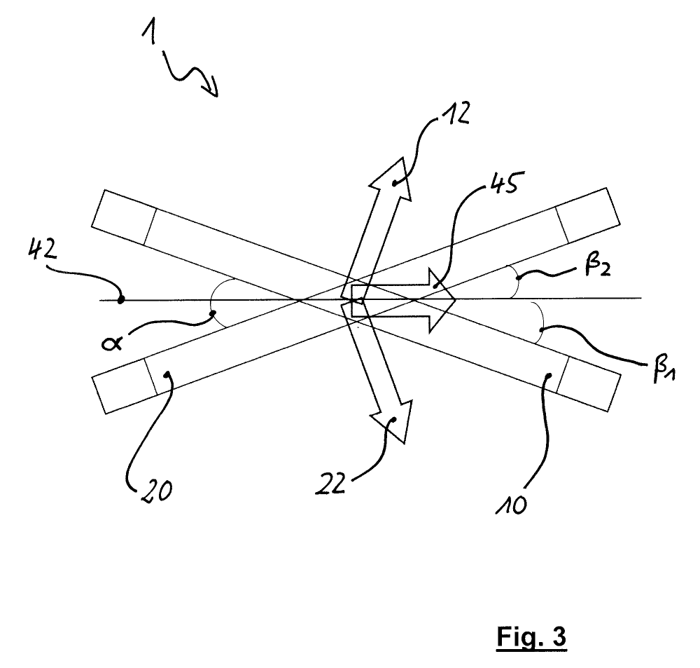

FIG. 3 shows a schematic side view of the coil arrangement shown in FIG. 1 with arrows 12, 22 and 45 showing the direction of the partial and resulting magnetic fields. Arrow 12 shows the direction of the partial magnetic field generated by coil 10, arrow 22 the partial magnetic field generated by coil 20. Arrow 45 shows the direction of the superimposed resulting magnetic field. Coils 10 and 20 generate dipole magnetic fields. With partial fields 12 and 22 of equal strength a superimposed dipole magnetic field 45 with high homogeneity can be generated. Coils 10 and 20 are arranged at symmetrical angles β1=β2 with respect to the horizontal plane 42. The superimposed resulting magnetic field 45 is directed in the horizontal direction. By variation of the angle a between the coils 10 and 20, the strength of the resulting magnetic field may be varied. By suitable variation of the angles β1 and β2 the direction of the superimposed resulting magnetic field 45 can be varied. This allows for the variance of the strength of the resulting field 45 and for the direction of the resulting field to be turned around the axis 40.

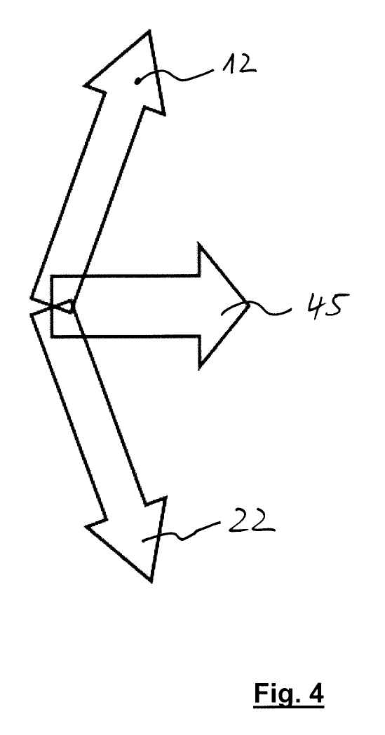

FIG. 4 shows the magnetic field vectors of the partial and resulting magnetic fields generated by the coil arrangement shown in FIG. 1. With coils 10 and 20 generating fields of equal strength, a superimposed resulting dipole magnetic field in horizontal direction is generated.

Coils 10 and 20 may be connected in series to be powered from one current source. This allows for easy provision of partial magnetic fields of equal strength. In an alternate embodiment the coils may be powered individually. The individual variation of the current through each of the coils allows the direction of the resulting magnetic field to be turned around the axis 40, while keeping the angle a at a suitable constant value.

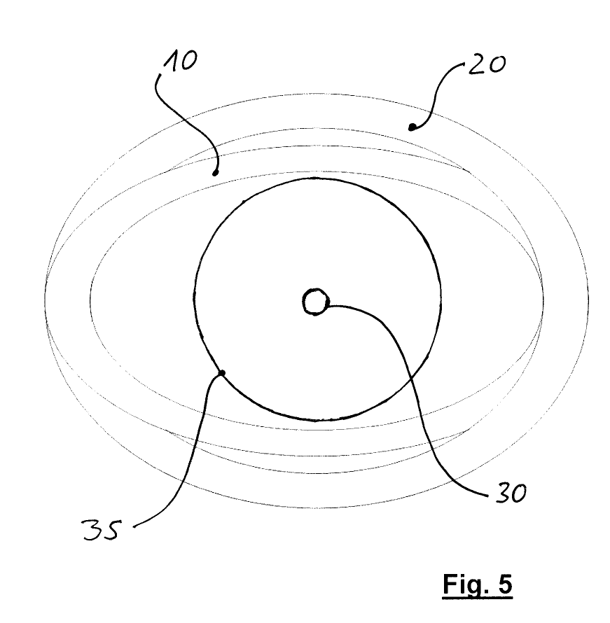

FIG. 5 shows a top view of the coil arrangement shown in FIG. 1 with a vessel 35 inserted into the coils. Coils 10 and 20 have an elliptical form. The smallest outer diameter of inner coil 10 is smaller than the smallest inner diameter of coil 20. The longest inner and outer diameter of coils 10 and 20 are equal. A cylindrical vessel 35 is inserted into the coils in such way that the vessel is encircled by both coils. The outer diameter of the vessel 35 is smaller than the smallest inner diameter of inner coil 10. The vessel is filled with a fluid from which the crystal is pulled, for example a melt. The coils are arranged in such way that they encircle the location 30 in the fluid where the crystal is pulled.

In an example embodiment of the method according to the present invention a melt is provided in a vessel 35. Two elliptical coils 10 and 20 are provided and arranged in a way to encircle the vessel and the melt contained therein. A crystal is pulled from the melt at a location 30 located in the region encircled by both coils.

All in all, the embodiments of the present invention may provide one or more of the following advantages. The coil arrangement allows the generation of a highly uniform dipole magnetic field for crystal pulling. The strength and direction of the resulting dipole magnetic field may be varied quite easily. The coil arrangement requires only a low number of coils, in preferred embodiments only two coils. Simple planar coils can be used. The arrangement is less complex and reduced in size with respect to prior art arrangements.

1. A coil arrangement for crystal pulling comprising two coils, characterized in that at least one of said two coils is arranged in a way to substantially surround the crystal and/or the fluid from which the crystal is pulled.

2. The coil arrangement according to claim 1, characterized in that both of said two coils are arranged in a way to substantially surround the crystal and/or the fluid from which the crystal is pulled.

3. The coil arrangement according to claim 1, characterized in that said two coils are canted with respect to each other.

4. The coil arrangement according to claim 3, characterized in that said two coils are arranged at a symmetrical angle with respect to a horizontal plane.

5. The coil arrangement according to claim 1, characterized in that said two coils provide a superimposed resulting dipole magnetic field.

6. The coil arrangement according to claim 1, characterized in that said two coils are nested.

7. The coil arrangement according to the preceding claim, characterized in that said coils are nested in such way that one coil is inside the other coil.

8. The coil arrangement according to claim 6, characterized in that said coils are nested like two connected rings.

9. The coil arrangement according to claim 1, characterized in that the cross-section of said coils is of round and/or elliptical and/or quadratic and/or rectangular shape.

10. The coil arrangement according to claim 1, characterized in that the longitudinal section of said coils has the shape of a rectangle and/or a parallelogram and/or curved shape.

11. The coil arrangement according to claim 1, characterized in that the angle between said coils can be varied.

12. The coil arrangement according to claim 1, characterized in that said coils are powered individually.

13. The coil arrangement according to claim 1, characterized in that said coils are connected in series to be operated from one current source.

14. The coil arrangement according to claim 1, characterized in that the coil arrangement comprises one or more further coils arranged in a way to substantially surround the crystal and/or the fluid the crystal is pulled from.

15. A method of forming a crystal comprising:
providing a fluid the crystal is pulled from;
providing two coils, wherein at least one of said two coils is arranged in a way to substantially surround the crystal and/or the fluid the crystal is pulled from; and
pulling the crystal from the fluid.
